(19) United States
(12) Patent Application Publication
(10) Pub. No.: US 2024/0292523 A1
(43) Pub. Date: Aug. 29, 2024

(54) METHOD FOR FORMING METAL LAYERS ON GLASS-CONTAINING SUBSTRATE, AND RESULTING DEVICE

(71) Applicant: CORNING INCORPORATED, CORNING, NY (US)

(72) Inventors: JOON-SOO KIM, Yongin-si (KR); YOUNG SUK LEE, Seoul (KR); BYUNGDOO MOON, Suwon-si (KR); HYUNG SOO MOON, Seoul (KR)

(21) Appl. No.: 18/571,937

(22) PCT Filed: Jun. 15, 2022
(86) PCT No.: PCT/US2022/033519

§ 371 Date: Dec. 19, 2023

Related U.S. Application Data
(60) Provisional application No. 63/214,874, filed on Jun. 25, 2021.

(51) Int. Cl. H05K 1/02; C03C 17/09; C03C 17/10; C03C 17/36; C23C 14/18; C23C 18/38; C23C 28/02; H05K 1/09; H05K 3/18

(52) U.S. Cl. CPC H05K 1/0271; C03C 17/09; C03C 17/10; C03C 17/3639; C03C 17/3649; C23C 14/185; C23C 18/38; C23C 28/023; H05K 1/09; C03C 2218/111; C03C 2218/154; H05K 3/181; H05K 2201/0338; H05K 2201/0341; H05K 2203/072

(57) ABSTRACT

A layered structure, an article such as circuit board including such a layered structure, and methods of making the same are provided. The layered structure includes a substrate comprising glass or glass ceramic, an adhesion layer disposed on the substrate, a seed layer disposed on the adhesion layer, a first conductive layer disposed on the seed layer, and a second conductive layer disposed on the first conductive layer. The seed layer includes a first metal material and has a first type of stress with respect to the substrate. The first conductive layer includes the first metal material and has a second type of stress with respect to the substrate. The second conductive layer includes a second metal material and has the first type of stress with respect to the substrate. The layered structure may further include additional pairs of alternating layers of the first and the second conductive layers.

### PRIORITY CLAIM AND CROSS-REFERENCE

This application claims the benefit of priority under 35 U.S.C. § 119 of U.S. Provisional Application Ser. No. 63/214,874 filed on Jun. 25, 2021, the content of which is relied upon and incorporated herein by reference in its entirety.

### FIELD

The disclosure relates to coating generally. More particularly, the disclosed subject matter relates to a method for forming a conductive coating for a glass circuit board, and a resulting device.

### BACKGROUND

Printed circuit board (PCB) mechanically supports and electrically connects electric components using patterned conductive layer on a substrate. PCB is an essential and base component widely used in most of electrical products with long history. Existing circuit board substrate, copper clad laminate (CCL), is a product form through lamination with copper foil on either one side or both sides of FR-4 as core substrate materials. FR-4 is a composite material composed of woven fiberglass cloth with an epoxy resin binder.

Electrical products become more complicated and thinner, and require a higher density of electric components with tiny size. As the electric components become smaller, the circuit patterns require higher accuracy and dimensional stability. There are new demands of circuit board for display application such as micro or mini LED emissive display and mini-LED backlight for LCD display. Display applications require a larger circuit board size than traditional PCB size. Due to tiny size of LED chips, the dimensional stability of circuit board substrate materials needs to be higher for higher pattern positional accuracy to improve LED transfer yield. Plastic substrate as an incumbent material and traditional PCB process are hard to satisfy the new requirements.

Existing printed circuit board (PCB) materials including glass-reinforced epoxy laminate such as FR4 and polyimide are widely used in the industry, but as demands for thin and small devices increase over time, glass having such high stability is asked to be applied into PCB materials. Glass or glass ceramic substrate is one of promising substrate to satisfy new requirements due to superior rigidity and flatness as well as higher thermal stability. Glass or glass ceramic material can replace the traditional substrate materials such as FR-4. Glass circuit boards (GCBs) have excellent thermal and mechanical properties due to low coefficient of thermal expansion (CTE) and high Young's modulus of glass.

Thermal stability of the substrates used is highly related to warpage issues during sequential PCB process such as the reflow process at high temperature. Those limitations caused from CTE mismatch between layers have been challenges. A CTE mismatch may cause problem such as warpage, blisters, and delamination.

### SUMMARY

The present disclosure provides a layered structure, an article or device such as circuit board including such a layered structure, and methods of making the same.

In accordance with some embodiments, the layered structure comprises a substrate comprising glass or glass ceramic, an adhesion layer disposed on the substrate, a seed layer disposed on the adhesion layer, a first conductive layer disposed on the seed layer, and a second conductive layer disposed on the first conductive layer. The seed layer comprises a first metal material, and may have a first type of stress with respect to the substrate. The first conductive layer comprises the first metal material, and may have a second type of stress with respect to the substrate. The second conductive layer comprises a second metal material, and may have the first type of stress with respect to the substrate. The first metal material is different from the second metal material. The first type of stress is different from the second type of stress. The first type of stress and the second type of stress are selected from tensile stress and compressive stress.

The adhesion layer comprises at least one of Ti, Ta, Cr, W, Mo, Zn, Pd, oxides thereof, nitrides thereof, and combinations thereof. In some embodiments, the adhesion layer comprises or is made of Ti. Each of the first metal material and the second metal material comprises at least one of Cu, Ni, Sn, Ti, Cr, W, Mo, and combinations thereof. For example, the first metal material comprises or is made of copper, and the second metal material comprises or is made of nickel in some embodiments.

In some embodiments, the first type of stress is tensile stress, while the second type of stress is compressive stress. The adhesion layer and the seed layer comprise sputtered coatings, and the first conductive layer and the second conductive layer comprise electroless plated coatings.

The layered structure may further comprise one or more additional pairs of alternating layers of the first conductive layer and the second conductive layer. For example, the layered structure may include from 1 to 4 additional pairs, i.e., from 1 to 5 pairs (in total), of alternating layers of the first conductive layer and the second conductive layer.

The first conductive layer and the second conductive layer have a suitable thickness ratio, for example, in a range of from about 10:1 to about 1:1.

The present disclosure also provides an article or device comprising the layered structure as described herein. For example, the article or the device is a circuit board. Such a circuit board may be glass or glass ceramic based.

In accordance with some embodiments, a layered structure comprises a substrate comprising glass or glass ceramic, an adhesion layer disposed on the substrate and comprising a suitable materials such as Ti, a seed layer disposed on the adhesion layer, a first conductive layer disposed on the seed layer, and a second conductive layer disposed on the first conductive layer. The seed layer comprises Cu, and has tensile stress with respect to the substrate. The first conductive layer comprises Cu, and has compressive stress with respect to the substrate. The second conductive layer comprises Ni, and has tensile stress with respect to the substrate.

In some embodiments, the adhesion layer and the seed layer comprise sputtered coatings, and the first conductive layer and the second conductive layer comprise or are electroless plated coatings.

In some embodiments, such a layered structure further comprises one or more additional pairs of alternating layers of the first conductive layer and the second conductive layer. For example, the layered structure includes from 1 to 4 additional pairs, i.e., from 1 to 5 pairs (in total), of alternating layers of the first conductive layer and the second conductive layer. The first conductive layer and the second conductive layer have a suitable thickness ratio, for example, in a range of from about 10:1 to about 1:1. In some embodiments, the first conductive layer has a thickness in a range of from about 5 microns to about 20 microns, and the second conductive layer have a thickness in a range of from about 0.1 micron to about 10 microns. In some embodiments, the second conductive layer comprises from about 0 to about 20 molar % of phosphorus in addition to Ni.

In another aspect, the present disclosure also provides a method of making the layered structure and/or related article such as a circuit board. Such a method comprises forming an adhesion layer on a substrate comprising glass or glass ceramic, forming a seed layer on the adhesion layer, forming a first conductive layer on the seed layer, and forming a second conductive layer on the first conductive layer. The seed layer comprises a first metal material and having a first type of stress with respect to the substrate. The first conductive layer comprises the first metal material, and has a second type of stress with respect to the substrate. The second conductive layer comprises a second metal material, and has the first type of stress with respect to the substrate. The first metal material is different from the second metal material. The first type of stress is different from the second type of stress, and they are either tensile or compressive stress. For example, the first type of stress is tensile stress and the second type of stress is compressive stress.

The adhesion layer comprises at least one of Ti, Ta, Cr, W, Mo, Zn, Pd, oxides thereof, nitrides thereof, and combinations thereof. Each of the first metal material and the second metal material comprises at least one of Cu, Ni, Sn, Ti, Cr, W, Mo, and combinations thereof. For example, in some embodiments, the first metal material comprises or is made of copper, and the second metal material comprises or is made of nickel.

In some embodiments, the adhesion layer is formed by sputtering, and the seed layer is formed by sputtering. The first conductive layer and the second conductive layer are formed using electroless plating, but have different type of stress with respect to the substrate.

The method may further comprise forming one or more additional pairs of alternating layers of the first conductive layer and the second conductive layer. From 1 to 4 additional pairs (1-5 pairs in total) of alternating layers of the first conductive layer and the second conductive layer are formed. The first conductive layer and the second conductive layer have a suitable thickness ratio in a range of from about 10:1 to about 1:1.

The layered structure and the article provided in the present disclosure are reliable with no overall residue stress and no warpage. The layered structure and the article or device have no other defects such as blisters and delamination. The conductive layers have high adhesion to the substrate, and also have good electrical conductivity. The metallization is uniform on a glass containing substrate, which can have a large size. The layered structure can be used as a circuit board or a portion of circuit board.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like reference numerals denote like features throughout specification and drawings.

FIG. 1 is a flow chart illustrating an exemplary method for forming a layered structure in accordance with some embodiments.

FIGS. 2A-2E are sectional views illustrating the structures in each step of the method of FIG. 1. FIG. 2E illustrates an exemplary layered structure in accordance with some embodiments.

FIG. 3 is a sectional view illustrating another exemplary layered structure in accordance with some embodiments.

FIG. 4 is a sectional view illustrating the definition of warpage.

FIG. 5 shows tensile stress values of three exemplary combinations of the adhesion layer and the seed layer exerted with respect to the substrate.

FIG. 6 shows tensile stress values of an exemplary combination of the adhesion layer and the seed layer made at different processing conditions.

FIG. 7 shows the values of compressive stress toward the substrate by electroless plated copper made at three different conditions.

FIG. 8A is a sectional view illustrating a layered structure including a seed layer and an adhesion layer over a glass substrate. FIG. 8B is a sectional view illustrating the warpage of the layered structure of FIG. 8A when the seed layer and the adhesion layer are formed by sputtering.

FIG. 9A is a sectional view illustrating an exemplary layered structure comprising a seed layer and an adhesion layer made by sputtering over a glass substrate, and the first conductive layer made by electroless plating, in accordance with some embodiments.

FIG. 9B is a sectional view illustrating no warpage of the layered structure of FIG. 9A.

FIG. 10 illustrates an example of minimizing warpage by changing the layered structure and resulting processing conditions from FIGS. 8A-8B to FIGS. 9A-9B, in accordance with some embodiments.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

For purposes of the description hereinafter, it is to be understood that the embodiments described below may assume alternative variations and embodiments. It is also to be understood that the specific articles, compositions, and/or processes described herein are exemplary and should not be considered as limiting.

Open terms such as “include,” “including,” “contain,” “containing” and the like mean “comprising.” These open-ended transitional phrases are used to introduce an open ended list of elements, method steps or the like that does not exclude additional, unrecited elements or method steps. It is understood that wherever embodiments are described with the language “comprising,” otherwise analogous embodiments described in terms of “consisting of” and/or “consisting essentially of” are also provided.

The transitional phrase “consisting of” and variations thereof excludes any element, step, or ingredient not recited, except for impurities ordinarily associated therewith.

The transitional phrase “consists essentially of,” or variations such as “consist essentially of” or “consisting essentially of” excludes any element, step, or ingredient not recited except for those that do not materially change the basic or novel properties of the specified method, structure or composition.

In the present disclosure the singular forms “a,” “an,” and “the” include the plural reference, and reference to a particular numerical value includes at least that particular value, unless the context clearly indicates otherwise. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

The terms “substantial,” “substantially,” and variations thereof as used herein are intended to note that a described feature is equal or approximately equal to a value or description. Moreover, “substantially similar” is intended to denote that two values are equal or approximately equal. In some embodiments, “substantially similar” may denote values within about 10% of each other, such as within about 5% of each other, or within about 2% of each other.

The present disclosure provides a layered structure, an article or device such as circuit board including such a layered structure, and methods of making the same.

For circuit board application, a conductive material layer is deposited on a substrate. Copper have been used for a conductive material due to its low electric resistivity, copper metallization, for example, copper foil lamination is an option for glass or glass ceramic substrates, but several disadvantages such as additional adhesive materials needed, via drilling on glass, and warpage from high film stress are associated with this process.

From thin film transistor (TFT) process, copper can be deposited on glass or glass ceramic by sputtering. However, copper does not adhere strongly to oxide substrate due to poor oxide forming ability. To promote adhesion strength, adhesion layer is used between copper and oxide substrate. A material for the adhesion layer should bind to oxide substrate via covalent bonds and to copper via metallic bond at the same time. After depositing adhesion layer, copper can be deposited for conductive layer. However, the sputtering process has several limitations. Due to low deposition rate and high film stress, deposited layer thickness is hard to be over 1 micron. For a thicker copper layer, electro-plating is used with conductive seed layer by sputtering process due to lower film stress and higher deposition rate.

However, there is thickness uniformity issue in electro-plating process because electrical current is hard to be uniform on overall substrate. The current is distributed from the edge connection, which provide by an external power. The current is higher at the edge than center of substrate. This causes thickness variation of electro-plated layer. If the substrate size is larger, the thickness uniformity is worse. In standard PCB size, 415×515 mm, thickness variation is larger than 15%.

In glass circuit boards (GCBs), a metal layer such as copper trace is required for electrical connectivity. However, when forming those metals on substrates with different CTE, severe residual stress occurs. The residual stress results in reliability issues including, but are not limited to, warpage, blisters, and delamination.

The metal layer such as a copper layer may have a residue stress with respect to the substrate, for example, a compressive stress toward the substrate, or a tensile stress away from the substrate. The direction of the stress might be normal to the planar surface of the substrate. When the residual stress of the metal layer is compressive stress, the warpage direction is convex, and blisters could happen. In the contrast, when the metal layer has tensile stress as residual stress, the warpage of the substrate and the metal layer happens in a concave direction, and delamination of the metal layer occurs.

In one aspect, the present disclosure provides a layered structure and a method to alleviate residue stress of metal layers by using at least two conductive layers (such as Cu and Ni layers) or multiple alternating pairs of two conductive layers on a substrate. The present disclosure also provides a suitable thickness ratio of the two conductive layers such as Cu and Ni layers to compensate residual stress each other. One of the objectives is to eliminate the warpage and other defects such as blisters and delamination so as to improve reliability of the layered structure or the resulting article or device. A single pair or multiple pairs of the two alternating conductive layers may also provide the required electrical conductivity based on the applications. One of the exemplary article or device is glass circuit board (GCB).

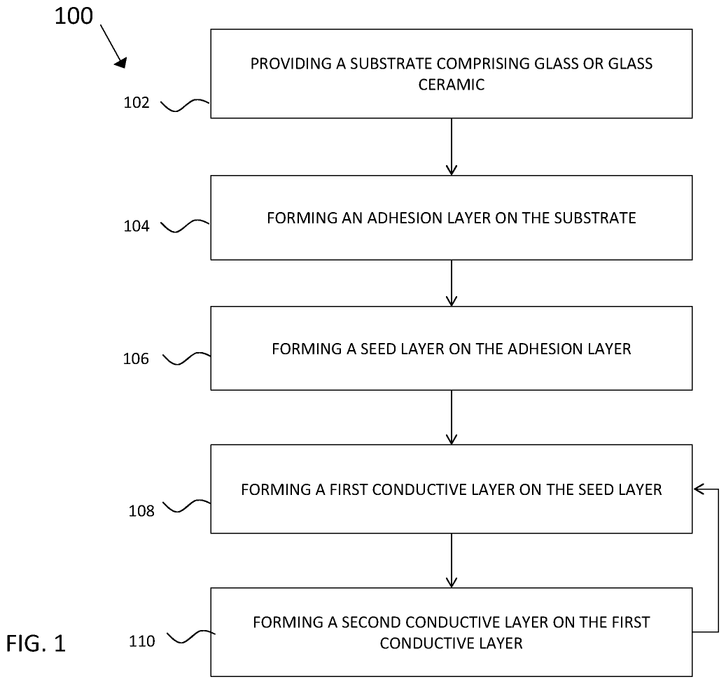

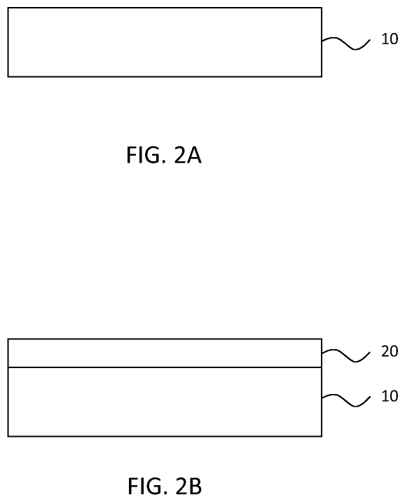

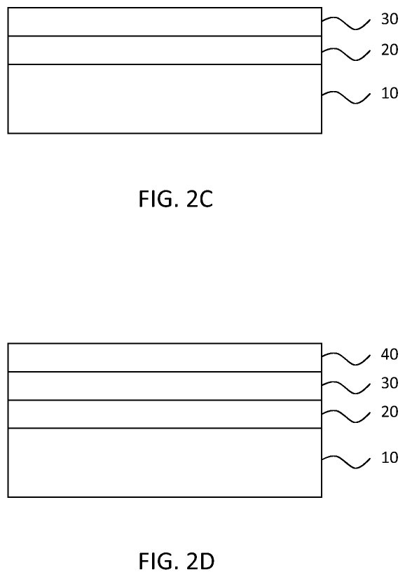

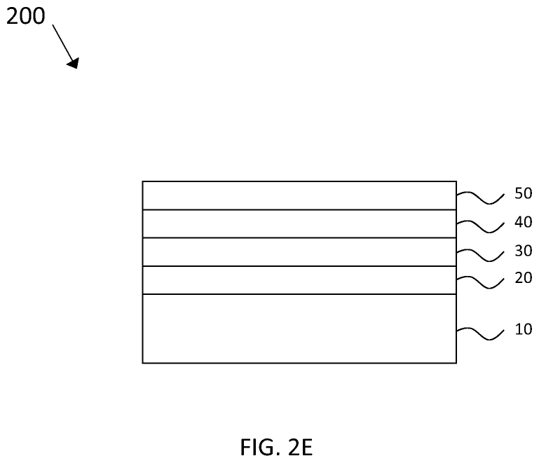

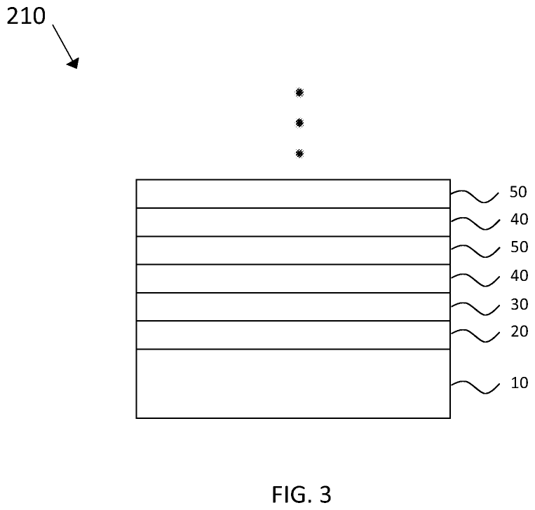

In FIGS. 1-3 and 9A-9B, like items are indicated by like reference numerals, and for brevity, descriptions of the structure, provided above with reference to the preceding figures, are not repeated. The methods described in FIG. 1 are described with reference to the exemplary structure described in FIGS. 2A-2E and 3.

Referring to FIG. 1, the present disclosure also provides an exemplary method 100 of making the layered structure 200 (or 210) and/or related article such as a circuit board comprising such a layered structure. The exemplary method 100 comprises the following steps described herein.

At step 102, a substrate 10 is provided. The substrate 10 is illustrated in FIG. 2A. The substrate 10 may comprise glass, glass ceramic, or any other suitable substrate such as a polymer based material. Examples of a substrate 10 include, but are not limited to, a thin layer of flat or curved glass panel. In some embodiments, the substrate 10 is optically transparent.

Unless expressly indicated otherwise, the term “glass article” or “glass” used herein is understood to encompass any object made wholly or partly of glass. Glass articles include monolithic substrates, or laminates of glass and glass, glass and non-glass materials, glass and crystalline materials, and glass and glass-ceramics (which include an amorphous phase and a crystalline phase).

The glass article such as a glass panel may be flat or curved, and is transparent or substantially transparent. As used herein, the term “transparent” is intended to denote that the article, at a thickness of approximately 1 mm, has a transmission of greater than about 85% in the visible region of the spectrum (400-700 nm). For instance, an exemplary transparent glass panel may have greater than about 85% transmittance in the visible light range, such as greater than about 90%, greater than about 95%, or greater than about 99% transmittance, including all ranges and subranges therebetween. According to various embodiments, the glass article may have a transmittance of less than about 50% in the visible region, such as less than about 45%, less than about 40%, less than about 35%, less than about 30%, less than about 25%, or less than about 20%, including all ranges and subranges therebetween. In certain embodiments, an exemplary glass panel may have a transmittance of greater than about 50% in the ultraviolet (UV) region (100-400 nm), such as greater than about 55%, greater than about 60%, greater than about 65%, greater than about 70%, greater than about 75%, greater than about 80%, greater than about 85%, greater than about 90%, greater than about 95%, or greater than about 99% transmittance, including all ranges and subranges therebetween.

Substrate 10 can be any suitable type of glass. Exemplary glasses can include, but are not limited to, aluminosilicate, alkali-aluminosilicate, borosilicate, alkali-borosilicate, aluminoborosilicate, alkali-aluminoborosilicate, soda-lime, alkali metal containing glass, alkaline earth metal containing glass, and other suitable glasses. Non-limiting examples of available glasses suitable for use as a light guide include, for instance, IRIS™, and GORILLA® glasses from Corning Incorporated. The glass article may be optionally strengthened. In some embodiments, the glass article may be strengthened mechanically by utilizing a mismatch of the coefficient of thermal expansion between portions of the article to create a compressive stress region and a central region exhibiting a tensile stress. In some embodiments, the glass article may be strengthened thermally by heating the glass to a temperature above the glass transition point and then rapidly quenching. In some other embodiments, the glass article may be chemically strengthening by ion exchange.

In the embodiments of the compositions such as glass or coating described herein, the concentrations of constituent components are specified in mole percent (mol. %), unless otherwise specified. The terms “free” and “substantially free,” when used to describe the concentration and/or absence of a particular constituent component in a composition, means that the constituent component is not intentionally added to the composition. However, the composition may contain traces of the constituent component as a contaminant or tramp in amounts of less than 0.01 mol. %.

The substrate 10 can have any suitable thickness. For example, the substrate 10 may have a thickness in a range of from 1 micron to 10 mm, for example, from 50 microns to 2 mm.

Referring back to FIG. 1, at step 104, an adhesion layer 20 is formed on the substrate 10. The resulting structure is shown in FIG. 2B. The adhesion layer 20 promotes adhesion of the conductive layer(s) onto the substrate 10. Unless expressly described otherwise, the term “disposed on” or “formed on” as described herein can be understood to encompass that one layer is directly formed on another layer, and the two layers have at least one portion or fully contacting with each other. The adhesion layer 20 can comprise or is made of any suitable material. For example, the adhesion layer 20 may be selected from Ti, Ta, Cr, W, Mo, Zn, Pd, oxides thereof, nitrides thereof, and combinations thereof. The adhesion layer 20 may be made by using any coating technique and may have any suitable thickness. For example, the adhesion layer 20 is made using a sputtering technique and has a tensile stress. Such a tensile stress has a direction normal to and away from the substrate 10. In some embodiments, the adhesion layer 20 comprises or is made of Ti made by sputtering. The sputtered Ti has a tensile stress with respect to the substrate 10.

At step 106, a seed layer 30 is formed on the adhesion layer 20. The resulting structure is shown in FIG. 2C. The seed layer 30 comprises a first metal material and having a first type of stress with respect to the substrate. The first type of stress is a tensile or compressive stress.

At step 108, a first conductive layer 40 is formed on the seed layer 30. The resulting structure is shown in FIG. 2D. The first conductive layer 40 comprises the first metal material, the same as that in the seed layer 30. The seed layer 30 may have a bigger grain size than that in the first conductive layer 40. The term “conductive” used herein is understood as “electrically conductive.” Further, the conductive layers described herein comprise metal, and are also thermally conductive.

The first conductive layer 40 has a second type of stress with respect to the substrate. The second type of stress is different from the first type of stress, and can be compressive or tensile stress.

At step 110, a second conductive layer 50 is formed on the first conductive layer 40. The resulting structure 200 is shown in FIG. 2D. The second conductive layer 50 comprises a second metal material, and has the first type of stress with respect to the substrate 10. The first metal material 40 and the second metal material 50 are different. The first type of stress is different from the second type of stress, and they are either tensile or compressive stress. For example, in some embodiments, the first type of stress is tensile stress and the second type of stress is compressive stress. The first metal material 40 and the second metal material 50 can be made using any suitable technique such as electroless plating, electrolytic plating, physical vapor deposition (PVD), and chemical vapor deposition (CVD).

Each of the first metal material 40 and the second metal material 50 can comprise or is made of a suitable metal material. Examples of suitable metal material include, but are not limited to Cu, Ni, Sn, Ti, Cr, W, Mo, and combinations thereof. For example, in some embodiments, the first metal material is copper, and the second metal material is nickel. The seed layer 30 is made of copper made by sputtering, and has a tensile strength. In some embodiments, the seed layer 30 comprises or is made of a catalyst such as palladium.

Electroless plating is a preferred method for metallization on glass, including forming the first metal material 40 and the second metal material 50. Electroless plating can improve thickness uniformity in a large size substrate such as a size bigger than an existing PCB size (415×515 mm). Electroless plating has no size limitation, and can be used for a substrate of any size. As a seed layer, sputtered copper layer or a catalyst such as palladium can be used. The catalyst can be used to promote thickness growth on an intended surface. In PCB industry, electroless plating is normally used for depositing conductive seed layer, which is thinner than 1 micron, before depositing thick metal layer by electro-plating, because electroless plating process is lower deposition rate than electro-plating and plated layer shows higher layer stress (compressive). The presence of stress in deposited layer can induce warpage of substrate and reliability issues, such as cracking, peeling off, buckling or blistering of coated layer. However, electroless plating methods are used in the methods provided in the present disclosure without any defects. The present disclosure provides the method for depositing metal layers on a glass or glass ceramic substrate having a large size with better thickness uniformity and no or lower warpage. Electroless plating method is used for metallization, which can improve thickness uniformity in a large size substrate. Warpage can be minimized or eliminated by balancing different stress. By controlling layer thickness and stress values, which is affected by process conditions and materials, warpage can be minimized or eliminated.

The first conductive layer 40 and the second conductive layer 50 have a suitable thickness ratio in a range of from about 10:1 to about 1:1, for example, about 2:1, about 3:1, about 4:1, about 5:1, about 6:1, about 7:1, about 8:1, about 9:1, or any other ratios between any of these two values. In some embodiments, the first conductive layer 40 has a thickness in a range of from about 5 microns to about 20 microns, for example, from about 5 microns to about 18 microns. The second conductive layer 50 has a thickness in a range of from 0.1 micron to about 10 microns, for example, from about 1 micron to about 5 microns. In some embodiments, the second conductive layer 50 comprises from about 0 to about 20 molar % of phosphorus in addition to Ni.

In some embodiments, the adhesion layer 20 is formed by sputtering, and the seed layer 30 is formed by sputtering. The adhesion layer 20 and the seed layer 30 have a tensile stress. The first conductive layer 40 (e.g., Cu) and the second conductive layer 50 (e.g., Ni) are formed using electroless plating, but have different type of stress with respect to the substrate 10. The electroless plating is faster than a sputtering coating process.

Referring to FIG. 1, the method 100 may further comprise steps of forming additional pairs of alternating layers of the first conductive layer 40 and the second conductive layer 50. This can be achieved by repeating steps 108 and 110. From 1 to 4 additional pairs (1-5 pairs in total) of alternating layers of the first conductive layer 40 and the second conductive layer 50 can be formed. The resulting structure is illustrated in FIG. 3. In some embodiments, the resulting structure includes 2, 3, 4, or 5 in total of pairs of alternating layers (e.g., Cu/Ni).

Referring to FIGS. 2 and 3, the layered structure 200 (or 210) comprises a substrate 10 comprising glass or glass ceramic, an adhesion layer 20 disposed on the substrate 10, a seed layer 30 disposed on the adhesion layer 20, a first conductive layer 40 disposed on the seed layer 30, and a second conductive layer 50 disposed on the first conductive layer 40. The seed layer 30 comprises a first metal material, and may have a first type of stress with respect to the substrate 10. The first conductive layer 40 comprises the first metal material, and may have a second type of stress with respect to the substrate 10. The second conductive layer 50 comprises a second metal material, and may have the first type of stress with respect to the substrate 10. The first metal material is different from the second metal material, and the first type of stress is different from the second type of stress. The first type of stress and the second type of stress are selected from tensile stress and compressive stress.

The adhesion layer 20 can be selected from Ti, Ta, Cr, W, Mo, Zn, Pd, oxides thereof, nitrides thereof, and combinations thereof. In some embodiments, the adhesion layer 20 comprises or is made of Ti. Each of the first metal material 40 and the second metal material 50 can be selected from Cu, Ni, Sn, Ti, Cr, W, Mo, and combinations thereof. For example, the first metal material is copper, and the second metal material is nickel in some embodiments.

In some embodiments, the first type of stress is tensile stress, while the second type of stress is compressive stress. The adhesion layer 20 and the seed layer 30 are sputtered coatings, and may have tensile stress. The first conductive layer 40 (e.g., Cu) and the second conductive layer 50 (e.g., Ni) are electroless plated coatings. The electroless copper may have compressive stress while the electroless Ni may have tensile stress.

Referring to FIG. 3, the layered structure 210 may further comprise additional pairs of alternating layers of the first conductive layer 40 and the second conductive layer 50. For example, the layered structure 210 may include from 1 to 5 pairs (in total) of alternating layers of the first conductive layer 40 and the second conductive layer 50. The first conductive layer 40 and the second conductive layer 50 have a suitable thickness ratio, for example, in a range of from about 10:1 to about 1:1 as described herein.

In some embodiments, a thin layer of electroplated Ni (as a catalyst or seed layer for the second conductive layer can be deposited on the seed layer (e.g., Cu), and then the second conductive layer 50 (e.g., electroless Ni) can be deposited on the electroplated Ni. A first conductive layer (e.g., Cu) is deposited on the second conductive layer (Cu). For the repeating pairs, Ni/Cu (e.g., Ni/Cu/Ni/Cu) can be deposited in order.

The present disclosure also provides an article or device comprising the layered structure 200 (or 210) as described herein. For example, the article is a circuit board. Such a circuit board may be glass or glass ceramic based.

In some preferred embodiments, a layered structure 200 or 210 (or the resulting article or device) comprises a substrate 10 comprising glass or glass ceramic, an adhesion layer disposed 20 on the substrate and comprising a suitable materials such as Ti, a seed layer 30 disposed on the adhesion layer 20, a first conductive layer 40 disposed on the seed layer 30, and a second conductive layer 50 disposed on the first conductive layer 40. The seed layer 30 comprises Cu, and has tensile stress with respect to the substrate 10. The first conductive layer 40 comprises Cu, and has compressive stress with respect to the substrate 10. The second conductive layer 50 comprises Ni, and has tensile stress with respect to the substrate 10. In some embodiments, the adhesion layer 20 and the seed layer 30 are sputtered coatings, and the first conductive layer 40 and the second conductive layer 50 are electroless plated coatings.

In some embodiments, such a layered structure 210 further comprises additional pairs of alternating layers of the first conductive layer 40 and the second conductive layer 50. For example, the layered structure 210 includes from 1 to 5 pairs (in total) of alternating layers of the first conductive layer 40 and the second conductive layer 50. The first conductive layer 40 and the second conductive layer 50 have a suitable thickness ratio, for example, in a range of from about 10:1 to about 1:1 as described above. In some embodiments, the first conductive layer 40 has a thickness in a range of from about 5 microns to about 20 microns, and the second conductive layer 50 have a thickness in a range of from about 0.1 micron to about 10 microns, as described above. In some embodiments, the second conductive layer comprises from about 0 to about 20 molar % of phosphorus in addition to Ni.

The layered structure and the article provided in the present disclosure are reliable with no overall residue stress and no warpage. They provide high adhesion to the substrate, and also have good electrical conductivity. A pair of Cu and Ni or multiple repeating pairs of alternating Cu/Ni layers is preferred in some embodiments. The layered structure in the present disclosure provides lower warpage and less defects compared to the structure that has a single main metal layer.

The present disclosure provides a novel method to alleviate the warpage phenomena by controlling electrically conductive metal layers (e.g., Cu/Ni). The warpage affects negatively following process in terms of processability and long-term reliability. In addition, thick metal layers can be achieved by adjusting thickness ratio of tCu/tNi without blisters, delamination, warpage, and other defects. The residual stress of metal layers limits forming thick layer that can provide sufficient current for devices. The method and the structure provided in the present disclosure allow metal layers to become thick enough to have low electrical resistance. It minimizes IR drop phenomena, so devices can be operated efficiently. Further, the structure of multiple metal layers including Ni in the present disclosure provides a lateral stack having high electrical conductivity in horizontal direction. Electroless Ni plating contains P, and it deceases electrical conductivity. However, in the present disclosure, lateral stack designs have Ni and Cu alternately. It is an advantage to allow an electrical circuit design to have long and narrow patterns, so large scalability, high density and complexity of the circuit design can be achieved.

In the previous trials, Ni was dispersed into a Cu layer, but such a metal layer has increased electrical resistivity and cannot be used to control stress. In the present disclosure, Cu and Ni layer are separate layers, and a Ni layer can be disposed directly on and contacting a Cu layer. In addition, electroless plated Cu layers were less than 2 microns thick. In the present disclosure, the thickness of a Cu layer can be at least and more than 5 microns.

### EXAMPLES

Examples 1-2: In Examples 1-2, a seed layer made of Cu (500 nm thick) was formed on a glass substrate using the sputtering technique. A copper layer (i.e. the first conductive layer) was deposited on the seed layer by using the electroless plating technique. The cross-sections of the samples were examined under field emission scanning electron microscope (FE-SEM). The first conductive layer has a thickness of about 9 microns and 11 microns, in Examples 1 and 2, respectively. The sheet resistance was tested with an average value from nine points. The first conductive layer of electroless Cu in Examples 1-2 had a sheet resistance of 2.13 mΩ/square and 2.14 mΩ/square, respectively. The coating thickness are uniform. The SEM images and the data of Examples 1-2 were compared to two Comparative Examples 1-2. Comparative Example 1 is similar to Example 1, except that the copper layer (about 10 microns thick) was deposited using an electroplating process. Comparative Example is a Cu clad laminate with a copper layer in a range of from about 16 microns to 20 microns. The Cu layer in Comparative Examples 1-2 had a sheet resistance of 1.87 mΩ/square and 0.94 mΩ/square, respectively.

Examples 1-2 show the feasibility of forming a thick (>2 um) copper layer by electroless plating on a seed layer of sputtered copper. Electrical performance of electroless plated copper layer is also as good as electroplated copper layer and CCL (copper clad laminate) in the comparatives examples. For copper thickness, it was identified that approximately 10 microns can be deposited by electroless plating. The growth rate of electroless plating is slower than electroplating, but electroless plating is easy to process multiple substrates in a bath because current supply and copper anode are not needed.

However, electroless plated layer has higher stress than electroplated layer. If metal layer is deposited on single side of substrate by electroless plating, warpage is inevitable. As the thickness of electroless plated layer increases, the warpage increases. To utilize the electroless plating for a large size and thicker copper deposition, the warpage should be minimized. The electroless plated layer of copper has compressive stress toward the substrate. Not to be bound by theory, if sputtered layer for adhesion/seed layer has tensile stress, the warpage should be lower after applying electroless plating due to opposite stress.

### Examples 3-11

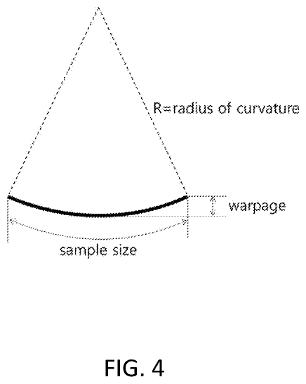

The samples with different sputtering conditions and adhesion layers were prepared, and the stress of the resulting was measured. The sputtered layer for the adhesion layer and the seed layer have tensile (or compressive) stress, depending on target materials and process conditions. Twenty pieces of sputtered on glass (50 mm×50 mm×0.4 mm of Corning EAGLE EX glass) samples were prepared in each process conditions. The radius of curvature was measured by non-contact laser scanning technology with FSM-5000TC equipment. The stress data were calculated by Stoney's equation. The warpage was also calculated from the radius of curvature. FIG. 4 is a sectional view illustrating the definition of warpage. After electroless plating, the radius of curvature was measured with same procedure.

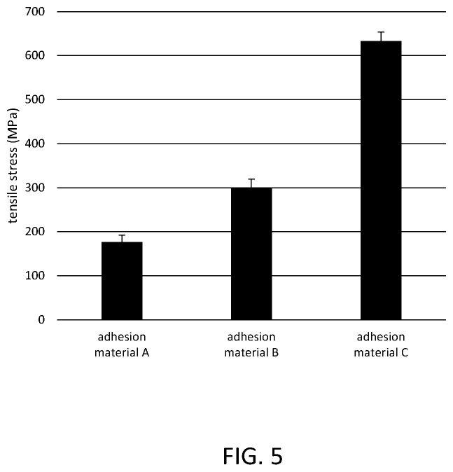

FIG. 5 shows tensile stress values of three exemplary combinations, Examples 3-5, of the adhesion layer and the seed layer exerted with respect to the substrate. In Examples 3-5, the adhesion layer (100 nm thick) of Ti, TiN, and TiO2 was deposited on glass substrates, respectively. These three adhesion materials are labelled as “adhesion material” A, B, and C, respectively, in FIG. 5. Other conditions were the same. A seed layer of Cu (500 nm thick) was deposited on the adhesion layer, respectively. As shown in FIG. 5, Examples 3-5 have a tensile stress in an increasing order.

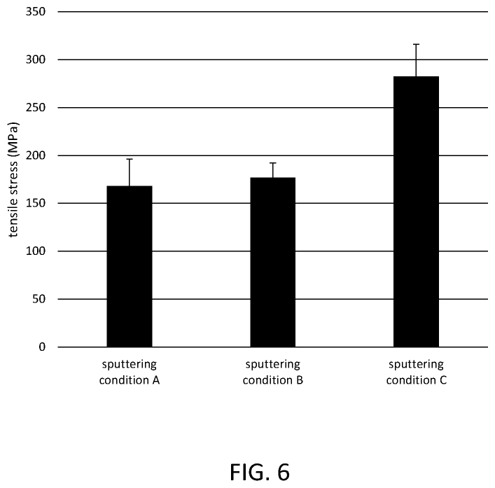

FIG. 6 shows tensile stress values of Examples 6-8, which were an exemplary combination of the adhesion layer and the seed layer made at different sputtering conditions. The adhesion layer and the seed layer were made of Ti (100 nm thick) and Cu (500 nm thick). The stress level increased when the vacuum level changed from 0.9 mTorr (sputtering A) to 2.0 mTorr (sputtering C) as shown in FIG. 6.

As shown in FIGS. 5-6, depending on sputtering process conditions and adhesion materials, adhesion/seed layers have different stress values. In another word, the stress values can be adjusted by selecting different materials and processing conditions.

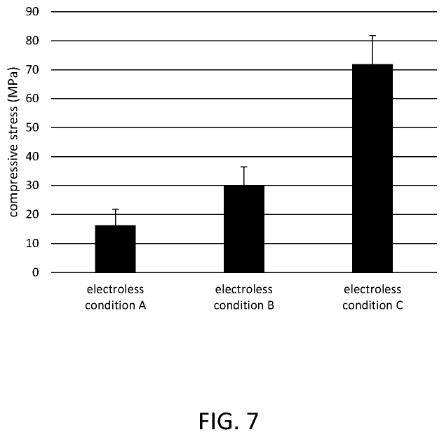

FIG. 7 shows the values of compressive stress toward the substrate by electroless plated copper made at three different conditions in Examples 9-11. The different electroless plating conditions are labeled as “electroless condition” A, B, and C, respectively, in FIG. 7. Electroless conditions A and B refer to that the Cu layer was deposited at 70 nm/minute, and 100 nm/minute, respectively. The seed layer was 500 nm thick of copper. Electroless condition C refers to that the Cu layer was deposited on a thinner (200 nm) copper seed layer at 100 nm/minute.

To demonstrate low warpage metallization by balancing between stress (tensile) of the adhesion and the seed layer, and stress (compressive) of electroless plated layer(s), adhesion material A, sputtering condition B, and electroless plating conditions B were selected in some experiments. Layer structures include adhesion material A layer (100 nm, e.g., Ti), copper seed layer (500 nm), and copper electroless plated layer (4 μm).

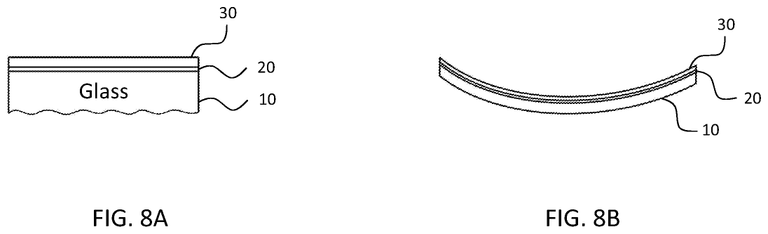

FIG. 8A illustrates a layered structure including a seed layer 30 and an adhesion layer 20 over a glass substrate 10. FIG. 8B illustrates the warpage of the layered structure of FIG. 8A when the seed layer 30 and the adhesion layer 20 are formed by sputtering.

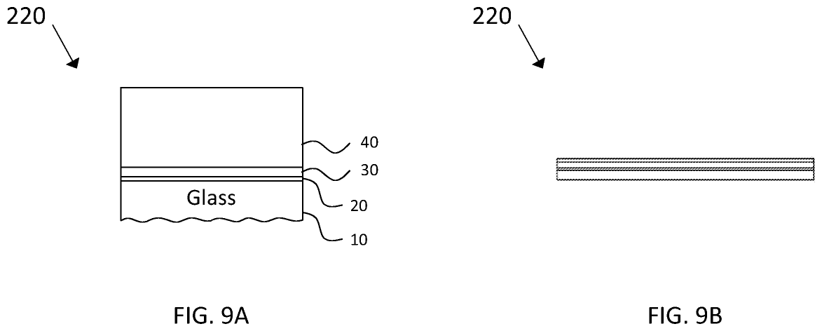

FIG. 9A illustrates an exemplary layered structure comprising a seed layer 30 and an adhesion layer 20 made by sputtering over a glass substrate 10, and the first conductive layer 40 made by electroless plating, in accordance with some embodiments. FIG. 9B illustrates no warpage of the layered structure of FIG. 9A.

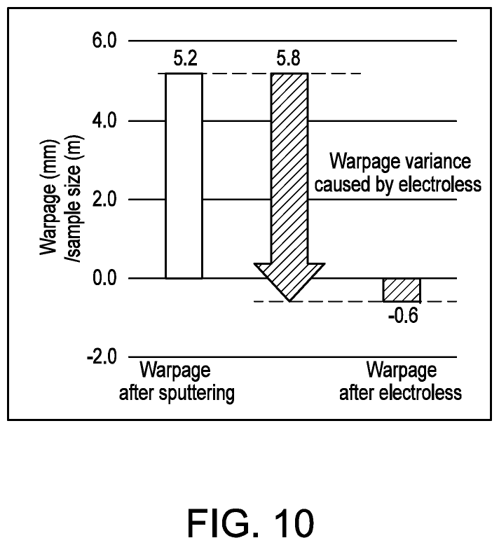

FIG. 10 illustrates an example of minimizing warpage by changing the layered structure and resulting processing conditions from FIGS. 8A-8B to FIGS. 9A-9B, in accordance with some embodiments.

Referring back to FIGS. 2E and 3, the thickness ratio of Cu and Ni (tCu/tNi) can be adjusted, and the thickness variations can be determined by Equation (1):

$$- σ N i / σ C u = t C u / t N i \qquad ( 1 )$$

It allows the metal layers to have low residual stress by compensating each stress, so the warpage and defects can be improved.

Table 1 shows one example of the thickness ratio of Cu and Ni (tCu/tNi) is presented for compensating the residual stress of each layer.

TABLE 1

| | Residual stress (MPa) | | | | |
|---|---|---|---|---|---|
| | Electroless Ni plating | Electroless | Thickness (μm) | | |
| # | (Including Ni strike) | Cu plating | Ni | Cu | t_{Cu}/t_{Ni} |
| 1 | 208.2 | −29.8 | 1.81 | 12.65 | 6.99 |
| 2 | | | 2.51 | 17.54 | |
| 3 | | | 1.99 | 13.91 | |
| 4 | | | 1.97 | 13.77 | |
| 5 | | | 1.97 | 13.77 | |

As shown in Table 1, under the stress ratio of electroless Cu and Ni, the thickness ratio of Cu and Ni (tCu/tNi) can be about 6.99 to improve the warpage. The way to form the Ni layer in the example was mainly done by electroless Ni plating that has about 10˜ 14% molar ratio of phosphorus. Electroplated Ni having a thickness of about 100 nm was deposited on Cu seed layer in advance (Ni strike). Such a thin Ni layer acts as a catalyst for electroless Ni plating. The thickness of the Ni thickness in Table 1 includes a total thickness of Ni (Ni strike and electroless Ni). The Cu layer was deposited by electroless Cu plating.

The degree of warpage is proportional to layer force (layer force=layer stress×layer thickness×width). If the layer force balance at the vertical direction (e.g., the direction normal to the substrate) is considered, width values can be unit width. For single-side metallization process by sputtered adhesion/seed layer and electroless plated metal layer, the force balance can be expressed in Equation (2):

$$Stress ( adhesion / seed layer ) \times thickness ( adhesion / seed layer ) ( \times width ) = stress ( electroless plated layer ) \times thickness ( electroless plated layer ) ( \times width ) . \qquad ( 2 )$$

Width term can be eliminated due to same values and layer stress values are absolute values. Low warpage can be achieved by controlling sputtering and electroless layer thickness and stress values. The layer stress of adhesion/seed layer can be controlled by sputtering process condition and adhesion/seed materials. Layer stress of electroless plated layer can also be controlled by electroless plating process conditions and electroless chemicals.

This method can be extended to multi-layer structures (e.g., including repeating pairs of the first and the second conductive layers) on single side or double side of a substrate. The warpage of multi-layer structure can be eliminated or minimized using Equations (3), (4), and (5) below. A multi-layer structure includes layer 1, layer 2 and layer n with different thickness. Depending on tensile or compressive stress, layer stress values are positive or negative. Each width is represented in unit width.

Low warpage of a multi-layer structure having coating layers on one side can be achieved by minimizing the sum of layer force using Equation (3) or (4):

$$Stress ( {L}_{1} ) \times thickness ( {L}_{1} ) \times width + stress ( {L}_{2} ) \times thickness ( {L}_{2} ) \times width + … stress ( {L}_{n} ) \times thickness ( {L}_{n} ) \times width = 0 or minimum value , or \qquad ( 3 )$$

$${\sum }_{k = 1}^{n} stress ( {L}_{k} ) \times thickness ( {L}_{k} ) = 0 or minimum values . \qquad ( 4 )$$

Low warpage of a multi-layer structure having coating layers on both sides (A and B sides) can be achieved by minimizing the sum of layer force using Equation (5):

$${\sum }_{k = 1}^{n} stress ( {L ( A )}_{k} ) \times thickness ( {L ( A )}_{k} ) - {\sum }_{m = 1}^{n} stress ( {L ( B )}_{m} ) \times thickness ( {L ( B )}_{m} ) = 0 or minimum values . \qquad ( 5 )$$

The layered structure and the article provided in the present disclosure are reliable with no overall residue stress and no warpage. They provide high adhesion to the substrate, and also have good electrical conductivity. A pair of the first and the second conductive layers (e.g., Cu/Ni) or multiple repeating pairs of alternating conductive (e.g., Cu/Ni) layers can be used. The layered structure in the present disclosure provides lower warpage and less defects compared to the structure that has a single main metal layer. The metallization is uniform on a glass containing substrate, which can have a large size. Glass panels can be used for manufacturing a device such as a display or a photovoltaic device. The layered structure can be used as a circuit board or a portion of circuit board. Metallized glass circuit board can be used for mini-LED BLU TV and self-emissive mini-LED displays for signage or TVs. High potential to be used as light board for premium and main-stream LCD TV models. Glass or glass ceramic circuit board for mmWave antenna and AP (Application Processor) package solution.

Although the subject matter has been described in terms of exemplary embodiments, it is not limited thereto. Rather, the appended claims should be construed broadly, to include other variants and embodiments, which may be made by those skilled in the art.

1. A layered structure, comprising:
a substrate comprising glass or glass ceramic;
an adhesion layer disposed on the substrate;
a seed layer disposed on the adhesion layer, the seed layer comprising a first metal material and having a first type of stress with respect to the substrate;
a first conductive layer disposed on the seed layer, the first conductive layer comprising the first metal material and having a second type of stress with respect to the substrate; and
a second conductive layer disposed on the first conductive layer, the second conductive layer comprising a second metal material and having the first type of stress with respect to the substrate,
wherein the first metal material is different from the second metal material,
wherein the first type of stress and the second type of stress are selected from tensile stress and compressive stress, and the first type of stress is different from the second type of stress.

2. The layered structure of claim 1, wherein the adhesion layer comprises at least one of Ti, Ta, Cr, W, Mo, Zn, Pd, oxides thereof, nitrides thereof, and combinations thereof.

3. The layered structure of claim 1, wherein the adhesion layer comprises Ti.

4. The layered structure of claim 1, wherein each of the first metal material and the second metal material comprises at least one of Cu, Ni, Sn, Ti, Cr, W, Mo, and combinations thereof.

5. The layered structure of claim 1, wherein the first metal material comprises copper, and the second metal material comprises nickel.

6. The layered structure of claim 1, wherein the first type of stress is tensile stress and the second type of stress is compressive stress.

7. The layered structure of claim 1, wherein the adhesion layer and the seed layer comprise sputtered coatings, and the first conductive layer and the second conductive layer comprise electroless plated coatings.

8. The layered structure of claim 1, further comprising one or more additional pairs of alternating layers of the first conductive layer and the second conductive layer.

9. The layered structure of claim 8, wherein the layered structure comprises from 1 to 4 additional pairs of alternating layers of the first conductive layer and the second conductive layer.

10. The layered structure of claim 1, wherein the first conductive layer and the second conductive layer have a thickness ratio in a range of from about 10:1 to about 1:1.

11. An article comprising the layered structure of claim 1.

12. The article of claim 11, wherein the article is a circuit board.

13. A layered structure, comprising:
a substrate comprising glass or glass ceramic;
an adhesion layer disposed on the substrate and comprising Ti;
a seed layer disposed on the adhesion layer, the seed layer comprising Cu and having tensile stress with respect to the substrate;
a first conductive layer disposed on the seed layer, the first conductive layer comprising Cu and having compressive stress with respect to the substrate; and
a second conductive layer disposed on the first conductive layer, the second conductive layer comprising Ni and having tensile stress with respect to the substrate.

14. The layered structure of claim 13, wherein the adhesion layer and the seed layer comprise sputtered coatings, and the first conductive layer and the second conductive layer comprise electroless plated coatings.

15. The layered structure of claim 13, further comprising one or more additional pairs of alternating layers of the first conductive layer and the second conductive layer.

16. The layered structure of claim 15, wherein the layered structure comprises from 1 to 4 additional pairs of alternating layers of the first conductive layer and the second conductive layer.

17. The layered structure of claim 13, wherein the first conductive layer and the second conductive layer have a thickness ratio in a range of from about 10:1 to about 1:1.

18. The layered structure of claim 13, wherein the first conductive layer has a thickness in a range of from about 5 microns to about 20 microns, and the second conductive layer has a thickness in a range of from about 0.1 micron to about 10 microns.

19. The layered structure of claim 13, wherein the second conductive layer comprises phosphorus having a content of from about 0 to about 20 molar %.

20.-29. (canceled)
